(19) United States
(12) Patent Application Publication
(10) Pub. No.: US 2006/0292498 A1
(43) Pub. Date: Dec. 28, 2006

(54) Method for forming contact hole in semiconductor device

(76) Inventors: Chang-Youn Hwang, Ichon-shi (KR); Dong-Duk Lee, Ichon-shi (KR); Ik-Soo Choi, Ichon-shi (KR); Hong-Gu Lee, Ichon-shi (KR)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/319,369

(22) Filed: Dec. 29, 2005

(30) Foreign Application Priority Data
Jun. 22, 2005 (KR) 2005-0053944

(51) Int. Cl. G03F 7/26

(52) U.S. Cl. 430/316; 430/313

(57) ABSTRACT

A method for forming a contact hole in a semiconductor device includes preparing a substrate including a bottom structure; forming an insulation layer such that the insulation layer covers the bottom structure; forming a silicon-rich oxynitride layer on the insulation layer; forming a photoresist pattern on the silicon-rich oxynitride layer; etching the silicon-rich oxynitride layer using the photoresist pattern as an etch mask, thereby obtaining hard masks; and etching the insulation layer using the photoresist pattern and the hard masks as an etch mask to form a contact hole exposing a portion of the bottom structure.

The present application claims the priority benefits of Korean patent application No. KR 2005-0053944, filed in the Korean Patent Office on Jun. 22, 2005, the entire contents of which are incorporated herein by reference.

### TECHNICAL FIELD

The present invention relates to a method for forming a contact hole in a semiconductor device; and, more particularly, to a method for forming a contact hole using a hard mask in 100 nm level dynamic random access memories. Although the present invention has been applied to a specific memory device, there can be other applications.

### DESCRIPTION OF RELATED ARTS

As semiconductor devices have been highly integrated, the design rule has also been decreased. Thus, fabrication processes are needed to be controlled more precisely. More precise control has been particularly needed in sub-100 nm dynamic random access memories (DRAMs), and researchers have intensively attempted to form metal contacts between a metal line and a bit line, between a conductive layer on a substrate and a bit line or between an active region of a substrate and an electrode of a capacitor.

However, the large scale of integration has pronounced a difference in heights between unit devices, and thus, forming deep contact holes for use in metal contacts becomes increasingly difficult. A photoresist pattern is used as an etch mask for forming the deep contact holes. The thickness, however, of the photoresist pattern needs to be decreased to meet the large scale of integration. Hence, when the photoresist pattern is solely used during the etching process for forming the deep contact holes, a bottom structure may be damaged by the etching process. This may occur because a portion of the photoresist pattern may be damaged due to an insufficient thickness margin of the photoresist pattern.

Thus, instead of using a photoresist pattern, hard masks are used for forming deep contact holes. Such hard masks may include nitride or polysilicon.

In the case of using a nitride layer as the hard mask for forming the deep contact holes, there may be a stress between the nitride layer and an oxide layer because of different compression stress levels, and thus, the nitride layer tends to be lifted up, resulting in degradation of device characteristics.

When a polysilicon layer is used as the hard mask for forming the deep contact holes, the polysilicon layer is less likely to be lifted up. However, the polysilicon layer should be formed to a thickness greater than about 3,000 Å to secure a sufficient etch margin for the deep contact holes. The thickness of the polysilicon layer may cause an elongated processing time and undesired delays. Furthermore, as the thickness of the polysilicon layer is increased, etching of the hard masks becomes more difficult, resulting in hard masks having a deteriorated profile. Hence, using the hard masks with the deteriorated profile may result in a decreased bottom portion area of the deep contact holes.

### SUMMARY

Consistent with the present invention, there is provided a method for forming a contact hole in a semiconductor device with improved device characteristics by preventing a nitride layer used as a hard mask from being lifted up due to different stress levels between the nitride layer and an oxide layer, which is formed beneath the nitride layer and used as an inter-layer insulation layer.

Consistent with an embodiment of the present invention, there is provided a method for forming a contact hole, including: preparing a substrate including a bottom structure; forming an insulation layer such that the insulation layer covers the bottom structure; forming a silicon-rich oxynitride layer on the insulation layer; forming a photoresist pattern on the silicon-rich oxynitride layer; etching the silicon-rich oxynitride layer using the photoresist pattern as an etch mask, to form hard masks; and etching the insulation layer using the photoresist pattern and the hard masks as an etch mask, to form a contact hole exposing a portion of the bottom structure.

### BRIEF DESCRIPTION OF THE DRAWINGS

The above and other features of the present invention will become better understood with respect to the following description of the embodiments given in conjunction with the accompanying drawings, in which:

FIGS. 1A to 1C are cross-sectional views illustrating a method for forming a contact hole in a semiconductor device in accordance with a specific embodiment consistent with the present invention;

FIG. 2A shows scanning electron microscopic images of a central part and an edge part of conventional silicon oxynitride based hard masks before and after stripping a photoresist pattern; and

FIG. 2B shows scanning electron microscopic images of a central part and an edge part of silicon-rich oxynitride based hard masks before and after a photoresist pattern in accordance with another specific embodiment consistent with the present invention.

### DETAILED DESCRIPTION

A method for forming a contact hole in a semiconductor device consistent with embodiments of the present invention will be described in detail with reference to the accompanying drawings. The thicknesses of layers and regions in the drawings are exaggerated for clarity, and when it is described that a layer is formed “on” another layer or a substrate, it means that the layer is formed directly on the other layer or the substrate, or a third layer can be interposed between them. Also, like reference numbers denote like elements even in different drawings.

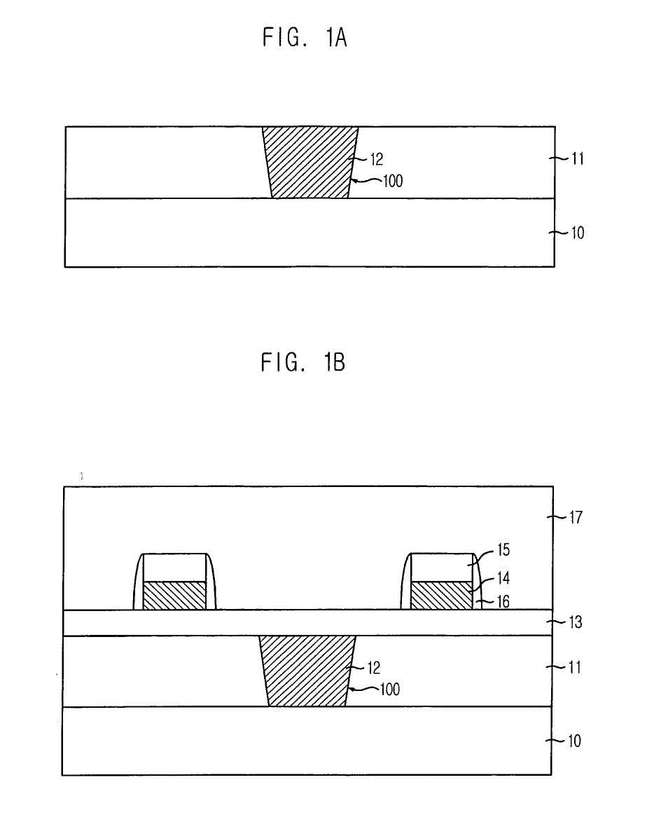

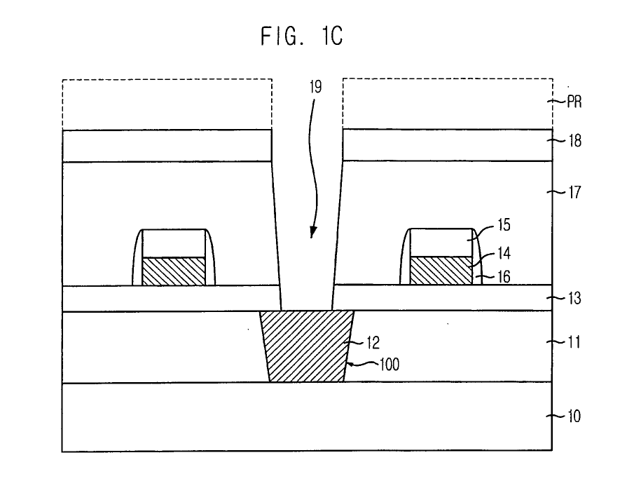

FIGS. 1A to 1C are cross-sectional views illustrating a method for forming a contact hole in a semiconductor device consistent with an embodiment of the present invention. Particularly, the embodied method is applied to form a contact hole in a dynamic random access memory (DRAM).

Referring to FIG. 1A, a first inter-layer insulation layer 11 is formed on a substrate 10. The first inter-layer insulation layer 11 can be a high density plasma (HDP) oxide layer, a borophosphosilicate glass (BPSG), a phosphosilicate glass (PSG) layer, plasma enhanced tetraethyl orthosilicate (PETEOS) layer, an undoped silicate (USG) layer, a fluorinated silicate glass (FSG) layer, a carbon doped oxide (CDO) layer, an organosilicate glass (OSG) layer, or a laminated layer thereof.

A chemical mechanical polishing (CMP) process is performed to planarize the first inter-layer insulation layer 11. The planarized first inter-layer insulation layer 11 is then etched to form an opening 100, and although not illustrated, a conductive material is filled into the opening 100 and then planarized, thereby forming a plug 12 for a landing plug contact. The plug 12 may be formed to contact an active region of the substrate 10, and may be formed of polysilicon.

Referring to FIG. 1B, a second inter-layer insulation layer 13 is formed on the first inter-layer insulation layer 11 and the plug 12. The second inter-layer insulation layer 13 includes an oxide-based material selected from the group consisting of HDP oxide, BPSG, PSG, PETEOS, USG, CDO, and OSG. The second inter-layer insulation layer 13 is planarized using a CMP process.

Bit lines 14 and first hard masks 15 are sequentially formed on predetermined portions of the second inter-layer insulation layer 13. The bit lines 14 include polysilicon or tungsten silicide. In the case of using a tungsten silicide layer, a thickness of the tungsten silicide layer ranges from approximately 200 Å to approximately 1,000 Å. If a barrier metal layer for the bit lines 14 is formed, the barrier metal layer is formed to a thickness ranging from approximately 100 Å to approximately 1,000 Å. Also, the first hard masks 15 include a material selected from the group consisting of nitride, nitrided oxide, tungsten nitride, polysilicon, oxide, amorphous carbon, and a combination thereof. The first hard masks 15 have a thickness ranging from approximately 2,000 Å to approximately 4,000 Å.

The first hard masks 15 are obtained by an etching process performed at approximately 20 mTorr to approximately 70 mTorr of pressure and approximately 300 W to approximately 1,000 W of power in an atmosphere of a gas mixture of CF₄/CHF₃/O₂/Ar. The tungsten silicide layer is etched at approximately 20 mTorr to approximately 70 mTorr of pressure and approximately 300 W to approximately 1,000 W of power in an atmosphere of a gas mixture of SF₆/BCl₃/N₂/Cl₂.

Spacers 16 are formed on sidewalls of the bit lines 14 and the first hard masks 15. The spacers 16 include a nitride material or an oxide-based material and have a thickness ranging from approximately 50 Å to approximately 150 Å.

A third inter-layer insulation layer 17 is formed over the above resulting structure. The third inter-layer insulation layer 17 is formed in a single layer or in a laminated layer using the same material for forming the second inter-layer insulation layer 13. If the third inter-layer insulation layer 17 is a HDP oxide layer, the HDP oxide layer is formed to a thickness ranging from approximately 5,000 Å to approximately 10,000 Å.

Referring to FIG. 1C, second hard masks 18 are formed on predetermined portions of the third inter-layer insulation layer 17. The second hard masks 18 have a thickness ranging from approximately 500 Å to approximately 2,000 Å. The hard masks 18 can include silicon oxynitride (SiON) with good adhesiveness to the third inter-layer insulation layer 17. A composition of SiON is changed to have a high content of silicon to prevent damage to a top structure due to a decreased etch selectivity of the second hard masks 18 when using a typical type of SiON. More specifically, the silicon content of the silicon-rich silicon oxynitride is in a range of approximately 20% to approximately 50%. The silicon-rich oxynitride can improve the etch selectivity and prevent interfacial layers from being lifted.

In more detail of the formation of the second hard masks 18, although not illustrated, a photoresist layer is formed on a hard mask layer and is patterned through a photo-exposure and developing process using a mask. Using the photoresist pattern PR, the hard mask layer is etched, thereby obtaining the second hard masks 18. The etching of the hard mask layer is carried out at approximately 20 mTorr to approximately 70 mTorr of power and approximately 50 W to approximately 500 W of power using a gas mixture of CF₄/CHF₃/O₂/Ar.

After the formation of the second hard masks 18, the third inter-layer insulation layer 17 is etched in-situ (i.e., at the same chamber where the etching of the hard mask layer for the second hard masks 18 takes place), thereby forming a storage node contact hole 19 exposing the plug 12. The etching of the third inter-layer insulation layer 17 is carried out at approximately 15 mTorr to approximately 50 mTorr of pressure and approximately 1,000 W to approximately 2,000 W of power in an atmosphere of a gas mixture of C₄F₈/C₅F₈/C₄F₆/CH₂F₂/Ar/O₂/Co/N₂.

The photoresist pattern PR is subsequently removed in-situ at approximately 10 mTorr to approximately 50 mTorr of pressure and approximately 50 W to approximately 500 W of power in an atmosphere of a gas mixture of CF₄/O₂/Ar. A cleaning process is performed to remove polymers generated during the etching of the third inter-layer insulation layer 17. In the cleaning process, a buffered oxide etchant including H₂SO₄ and H₂O₂ in a ratio of approximately 300:1 is used.

Although not illustrated, a nitride layer is formed over the storage node contact hole 19 and the second hard masks 18 and is etched to form spacers on inner walls of the storage node contact hole 19. The spacers have a thickness of approximately 100 Å to approximately 150 Å. The etching process for forming the spacers is carried out at approximately 30 mTorr to approximately 60 mTorr of pressure and approximately 1,000 W to approximately 1,800 W of power in an atmosphere of a gas mixture of CF₄/CHF₃/O₂/Ar. The spacers prevent the bit lines 14 from contacting a subsequent storage node contact plug when the bit lines 14 are exposed by the storage node contact hole 19 due to a decreased overlay margin or mask misalignment.

Although not illustrated, the aforementioned storage node contact plug is formed by filling the storage node contact hole 19. The storage node contact plug may be a polysilicon layer formed to a thickness of approximately 1,500 Å to approximately 3,000 Å.

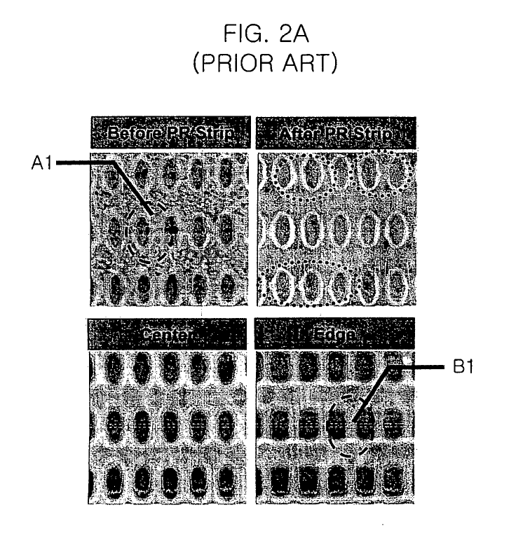

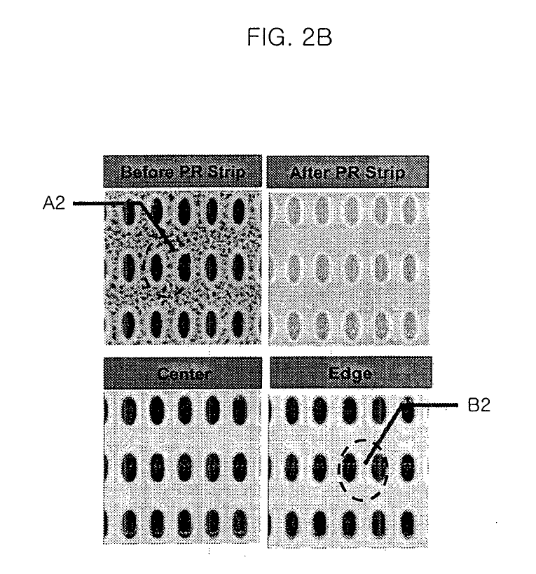

FIG. 2A shows scanning electron microscopic images of a central part and an edge part of SiON-based hard masks before and after stripping a photoresist pattern (PR). FIG. 2B shows scanning electron microscopic images of a central part and an edge part of hard masks based on silicon-rich oxynitride before and after a photoresist pattern (PR) consistent with another embodiment of the present invention.

In the case of using SiON as the hard mask material, before the photoresist pattern is stripped, the hard masks may be damaged due to an insufficient margin of the photoresist pattern. The damaged hard masks are expressed as ‘A1’ in FIG. 2A. A reference denotation ‘B1’ denotes a damaged inter-layer insulation layer resulting after the inter-layer insulation layer is etched to form a storage node contact hole due to the damaged hard masks caused by the insufficient margin of the photoresist pattern.

Consistent with embodiments of the present invention, when silicon-rich oxynitride is used as the hard mask material for second hard masks 18, and as illustrated with a reference denotation ‘A2’ in FIG. 2B, before the photoresist pattern is stripped, damage to the hard masks caused by an insufficient margin of the photoresist pattern is prevented. Also, as illustrated with a reference denotation ‘B2’, after an inter-layer insulation layer is etched to form a storage node contact hole, damage to the inter-layer insulation layer due to the damaged hard masks caused by the insufficient margin of the photoresist pattern is prevented.

In Table 1 below, sequential steps of forming hard masks based on polysilicon and sequential steps of forming hard masks based on silicon-rich oxynitride are briefly described. As shown in Table 1, when silicon-rich oxynitride is used as the hard mask material, 5 steps can be omitted from the total number of the steps.

TABLE 1

| STEP | | |
|---|---|---|
| (Number | | |
| of | | Silicon-rich oxynitride based |
| processes) | Polysilicon based hard mask | hard mask |
| 1 | Oxide based inter-layer | Oxide based ILD formation |
| | insulation (ILD) layer | |
| | formation | |
| 2 | polysilicon based hard mask | Silicon-rich oxynitride based |
| | formation | hard mask formation |
| 3 | Key open mask | omit |
| 4 | Key open etch | omit |
| 5 | Photoresist pattern | omit |
| | strip/cleaning | |
| 6 | mask | mask |
| 7 | Polysilicon based hard | omit |
| | mask etch | |
| 8 | PR strip/cleaning | omit |
| 9 | Oxide based ILD etch | Oxide based ILD etch |

Consistent with the embodiments of the present invention, using silicon-rich oxynitride as a hard mask material for forming a storage node contact hole can prevent a hard mask from being lifted up from an inter-layer insulation layer formed beneath the hard mask. As a result, device characteristics can be improved. Also, fabrication processes can be stably performed, thereby improving yields of semiconductor devices. Since the number of fabrication processes can be reduced when silicon-rich oxynitride is used as the hard mask material, a manufacturing cost can be reduced.

While the present invention has been described with respect to certain embodiments, it will be apparent to those skilled in the art that various changes and modifications may be made without departing from the spirit and scope of the invention as defined in the following claims.

What is claimed is:

1. A method for forming a semiconductor device, comprising:
preparing a substrate to have a bottom structure;
forming an insulation layer on the substrate such that the insulation layer covers the bottom structure;
forming a silicon-rich oxynitride layer on the insulation layer;
forming a photoresist pattern on the silicon-rich oxynitride layer;
etching the silicon-rich oxynitride layer using the photoresist pattern as an etch mask to form hard masks; and
etching the insulation layer using the photoresist pattern and the hard masks as an etch mask to form a contact hole exposing a portion of the bottom structure.

2. The method of claim 1, wherein forming the silicon-rich oxynitride layer comprises forming the silicon-rich oxynitride layer to have approximately 20% to approximately 50% silicon.

3. The method of claim 1, wherein etching the silicon-rich oxynitride layer and etching the insulation layer comprises etching the silicon-rich oxynitride layer and etching the insulation layer in-situ in the same chamber.

4. The method of claim 1, wherein etching the silicon-rich oxynitride layer comprises etching the silicon-rich oxynitride layer at a pressure of approximately 20 mTorr to approximately 70 mTorr and a power of approximately 50 W to approximately 500 W in an atmosphere of a gas mixture of CF₄/CHF₃/O₂/Ar.

5. The method of claim 1, wherein etching the insulation layer comprises etching the insulation layer at a pressure of approximately 15 mTorr to approximately 50 mTorr and a power of approximately 1,000 W to approximately 2,000 W in an atmosphere of a gas mixture of C₄F₈/C₅F₈/C₄F₆/CH₂F₂/Ar/O₂/Co/N₂.

6. The method of claim 1, further comprising:
removing the photoresist pattern after forming the contact hole.

7. The method of claim 6, wherein removing the photoresist pattern comprises removing the photoresist pattern in situ in the same chamber where the silicon-rich oxynitride layer and the insulation layer are etched using a specific recipe of: a gas mixture of CF₄/O₂/Ar; a pressure of approximately 10 mTorr to approximately 50 mTorr; and a power of approximately 50 W to approximately 500 W.

8. The method of claim 6, further comprising:
forming spacers on inner walls of the contact hole after removing the photoresist pattern.

9. The method of claim 8, wherein forming the spacers comprises:
forming a nitride layer over the contact hole and the hard masks; and
etching the nitride layer such that a portion of the nitride layer remains on the inner walls of the contact hole.

10. The method of claim 1, wherein etching the nitride layer comprises etching the nitride layer using a specific recipe of: a gas mixture of CF₄/CHF₃/O₂/Ar; a pressure of approximately 30 mTorr to approximately 60 mTorr; and a power of approximately 1,000 W to approximately 1,800 W.
